(19) United States
(12) Patent Application Publication
(10) Pub. No.: US 2023/0009114 A1
(43) Pub. Date: Jan. 12, 2023

(54) METHOD FOR FORMING SEMICONDUCTOR STRUCTURE AND SEMICONDUCTOR STRUCTURE

(71) Applicant: CHANGXIN MEMORY TECHNOLOGIES, INC., Hefei City (CN)

(72) Inventor: Ling-Yi CHUANG, Hefei (CN)

(21) Appl. No.: 17/668,736

(22) Filed: Feb. 10, 2022

Related U.S. Application Data
(63) Continuation of application No. PCT/CN2021/120261, filed on Sep. 24, 2021.

(30) Foreign Application Priority Data
Jul. 12, 2021 (CN) 202110783703.6

(51) Int. Cl. H01L 21/304; H01L 21/47; H01L 21/768

(52) U.S. Cl. CPC H01L 21/3043; H01L 21/47; H01L 21/76877

(57) ABSTRACT

A method for forming a semiconductor structure is provided. The method includes: providing a substrate; forming a groove in the substrate, in which a side wall of the groove is formed by sequential connection of a plurality of pits recessed into the substrate; forming a first material in the groove, in which the pits are completely filled with the first material; and exposing and developing the first material in the groove to obtain a through via structure.

### CROSS-REFERENCE TO RELATED APPLICATIONS

The present application is a U.S. continuation application of International Application No. PCT/CN2021/120261, filed on Sep. 24, 2021, which claims priority to Chinese Patent Application No. 202110783703.6, filed on Jul. 12, 2021. International Application No. PCT/CN2021/120261 and Chinese Patent Application No. 202110783703.6 are incorporated herein by reference in their entireties.

### TECHNICAL FIELD

The present disclosure relates to but is not limited to a method for forming a semiconductor structure and a semiconductor structure.

### BACKGROUND

Through Silicon Via (TSV) technology enables vertical interconnections of chip-to-chip or wafer-to-wafer. At present, Bosch etching is commonly used to form a through silicon via with a high aspect ratio.

However, the side wall of the through via formed by Bosch etching is not smooth, which brings great difficulties to the uniform deposition of the subsequent films.

### SUMMARY

An embodiment of the present disclosure provides a method for forming a semiconductor structure, including: providing a substrate; forming a groove in the substrate, in which a side wall of the groove is formed by sequential connection of a plurality of pits recessed into the substrate; forming a first material in the groove, in which the pits are completely filled with the first material; and exposing and developing the first material in the groove to obtain a through via structure.

A further embodiment of the present disclosure provides a semiconductor structure. The semiconductor structure includes: a substrate and a through via structure in the substrate, in which a plurality of pits that are recessed into the substrate are provided between a side wall of the through via structure and the substrate and the plurality of pits are sequentially connected along a direction in which the through via structure extends; and a first material completely filled in the plurality of pits.

### BRIEF DESCRIPTION OF THE DRAWINGS

FIG. 1 illustrates a schematic diagram of a semiconductor structure according to an embodiment of the present disclosure.

FIG. 2 illustrates a flowchart of a method for forming a semiconductor structure according to an embodiment of the present disclosure.

FIGS. 3A-3I illustrate process flow diagrams of a method for forming a semiconductor structure according to an embodiment of the present disclosure.

FIG. 4 illustrates a schematic diagram of a semiconductor structure according to an embodiment of the present disclosure.

### DETAILED DESCRIPTION

The exemplary embodiments disclosed herein will be described in more detail below with reference to the accompanying drawings. Although the exemplary embodiments of the present disclosure are shown in the accompanying drawings, it should be understood that the present disclosure may be implemented in various manners without being limited by the specific embodiments set forth herein. Rather, these embodiments are provided to enable a more thorough understanding of the present disclosure and to enable the scope of the present disclosure to be entirely conveyed to those skilled in the art.

In the following description, a number of specific details are given to provide a more thorough understanding of the present disclosure. However, it will be apparent to those skilled in the art that the present disclosure may be implemented without one or more of these details. In other examples, some technical features known in the art will not be described to avoid confusion with the present disclosure. That is, not all of the features in an actual embodiment will be described herein, and well-known functions and structures will not be described in detail.

In the drawings, the dimensions of the layers, regions, elements and their relative dimensions may be exaggerated for clarity. The same reference numerals denote the same elements throughout the description.

It should be understood that when an element or layer is described as being “on”, “adjacent to”, “connected to” or “coupled to” other elements or layers, it can be directly on, adjacent to, connected to, or coupled to the other elements or layers, or intervening elements or layers may be present. In contrast, when an element is described as being “directly on”, “directly adjacent to”, “directly connected to” or “directly coupled to” other elements or layers, no intervening elements or layers are present. It should be understood that although the terms “first”, “second”, “third”, etc. may be used to describe various elements, components, regions, layers and/or portions, these elements, components, regions, layers and/or portions should not be limited by these terms. These terms are only used to distinguish one element, component, region, layer or portion from another element, component, region, layer or portion. Therefore, without departing from the teachings of the present disclosure, a first element, component, region, layer or portion discussed below may be represented as a second element, component, region, layer or portion. When the second element, component, region, layer or portion is discussed, it does not mean that the first element, component, region, layer or portion is necessarily present in the present disclosure.

Spatial relationship terms such as “under . . . ”, “below . . . ”, “below”, “underneath . . . ”, “on . . . ”, “above”, etc., will be used here for convenience to describe the relationship between one element or feature and other elements or features shown in the figures. It should be understood that in addition to the orientations shown in the figures, the spatial relationship terms are intended to include different orientations of devices in use and operation. For example, if the device in the drawings is turned over, elements or features described as “underneath” or “below.” or “under” other elements will be oriented “above” the other elements or features. Therefore, the exemplary terms “below . . . ” and “under . . . ” may include both an up orientation and a down orientation. The device can be otherwise oriented (being rotated by 90 degrees or other orientation) and the spatial descriptors used here are interpreted accordingly.

The terms used here are only intended to describe specific embodiments and should not be construed as limitations to the present disclosure. As used herein, the singular forms of “a”, “an” and “the/said” are also intended to include plural forms, unless otherwise indicated clearly in the context. It should also be understood that the terms “constituted” and/or “including”, as used in this specification, specify the presence of the described features, integers, steps, operations, elements and/or components, but do not exclude the presence or addition of one or more other features, integers, steps, operations, elements, components, and/or groups. As used herein, the term “and/or” includes any and all combinations of related listed items.

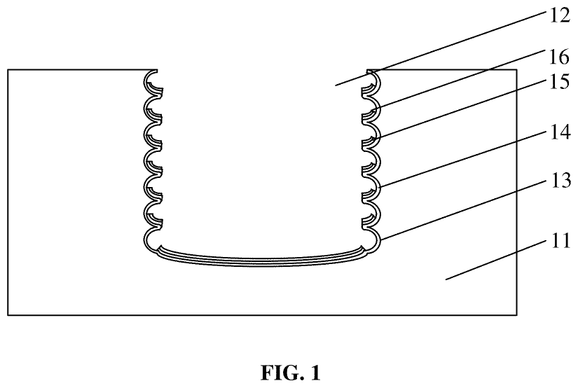

As illustrated in FIG. 1, the semiconductor structure includes a substrate 11 and a through via 12 in the substrate 11. The through via 12 is formed in the substrate 11 by Bosch etching, so that the side wall of the through via 12 is uneven, including a plurality of scallop-like pits 13 distributed continuously.

The semiconductor structure further includes an insulating layer 14 that covers the side wall and the bottom of the through via 12. The insulating layer 14 is used for separating the substrate 11 from a conductive material to be deposited in the through via subsequently. The insulating layer 14 is generally formed by in situ oxidation, so that the insulating layer 14 has good conformal coverage and can completely cover the side wall of the through via 12.

The semiconductor structure generally further includes a barrier layer 15 for blocking diffusion of a conductive material to be formed subsequently in the through via structure toward the substrate 11 and a seed layer 16 for subsequently forming the conductive material by electroplating.

However, unlike the insulating layer 14, which is capable of completely covering the side wall of the through via 12, the barrier layer 15 and the seed layer 16 cannot be continuously deposited, resulting in the formation of voids during subsequently electroplating the conductive material in the through via 12 and the occurrence of current leakage, which will affect the reliability of the semiconductor structure.

In view of the above, the following technical solutions in the embodiments of the present disclosure are proposed.

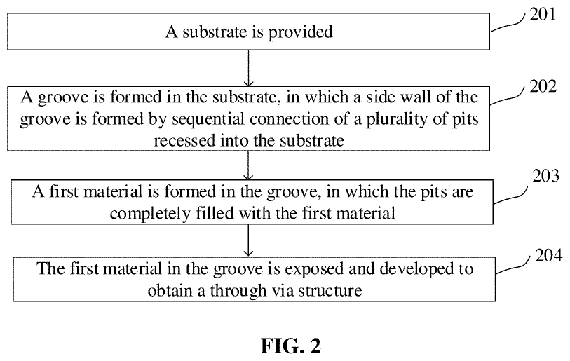

An embodiment of the present disclosure provides a method for forming a semiconductor structure. As illustrated in FIG. 2, the method includes the following steps.

In S201, a substrate is provided.

In S202, a groove is formed in the substrate, in which a side wall of the groove is formed by sequential connection of a plurality of pits recessed into the substrate.

In S203, a first material is formed in the groove, in which the pits are completely filled with the first material.

In S204, the first material is exposed and developed in the groove to obtain a through via structure.

In the embodiment of the present disclosure, the pits are recessed into the substrate, and the first material in the pits would not be irradiated by light during exposure, so that the first material in the pits is retained when developing to form the through via structure. As a result, the through via structure obtained after developing has a smooth side wall, which facilitates uniform deposition of a subsequent thin film and improves reliability of the semiconductor structure.

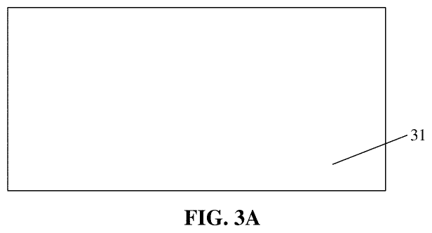

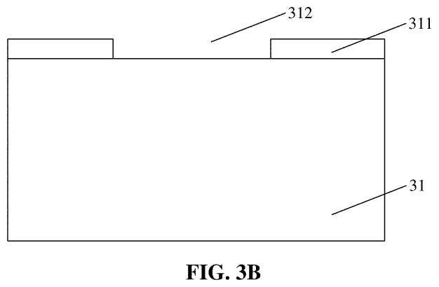

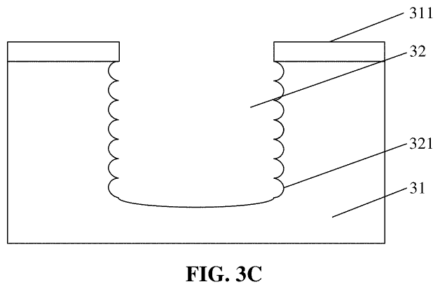

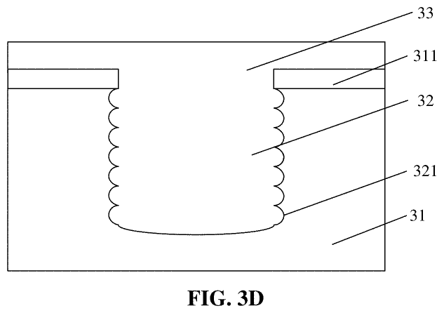

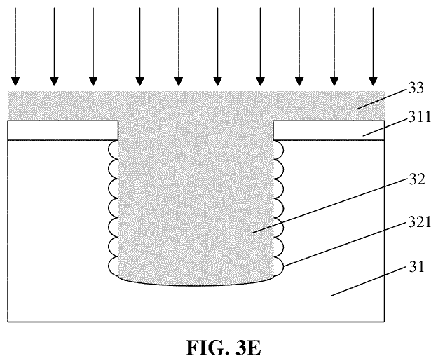

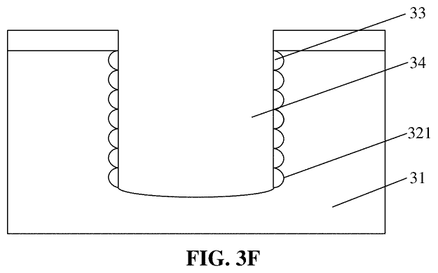

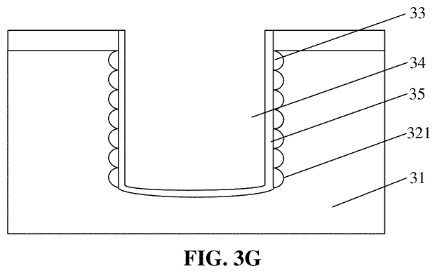

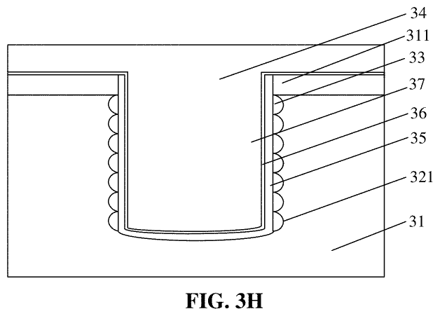

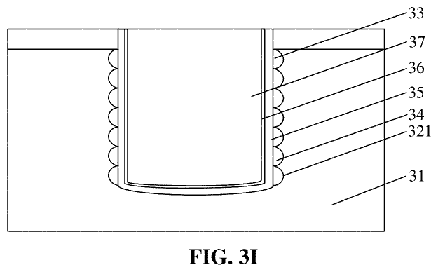

In order to make the above objectives, features and advantages of the present disclosure more clear and understandable, a method for forming a semiconductor structure provided in an embodiment of the present disclosure will be further described with reference to FIGS. 3A-3I.

Firstly, S201 is performed to provide the substrate 31, as illustrated in FIG. 3A.

The substrate 31 may be a semiconductor substrate, for example, an elementary semiconductor material (e.g., a silicon (Si) substrate, a germanium (Ge) substrate, etc.), a III-V compound semiconductor material (e.g., a gallium nitride (GaN) substrate, a gallium arsenide (GaAs) substrate, an indium phosphide (InP) substrate, etc.), a II-VI compound semiconductor material, an organic semiconductor material, or other semiconductor materials known in the art.

Next, as illustrated in FIG. 3C, S202 is performed to form a groove 32 in the substrate 31. A side wall of the groove 32 is formed by sequential connection of a plurality of pits 321 recessed into the substrate 31.

Specifically, the groove 32 is formed in the substrate 31 using a Bosch etching process. In the Bosch etching process, the etching process and the protection process are performed alternately, in order to reduce the lateral etching. As a result, a plurality of scallop-like pits 321 are formed in the side wall of the groove formed by etching. The scallop-like pits 321 would affect the continuity of the films to be formed subsequently and greatly reduce the reliability of the semiconductor structure.

In an embodiment, as illustrated in FIG. 3B, a first insulating layer 311 is provided on the surface of the substrate 31. An opening 312 exposing the surface of the substrate 31 is formed in the first insulating layer 311 prior to forming the groove 32. The position of the opening 312 corresponds to the position of the groove 32.

In a specific embodiment, the first insulating layer 311 includes but is not limited to silicon oxide. Other insulating materials may be used as the first insulating layer 311. In a specific embodiment, the first insulating layer 311 may be formed on the surface of the substrate 31 by in situ oxidation.

Next, S203 is performed, as shown in FIG. 3D, to form a first material 33 in the groove 32, and the pits 321 are completely filled with the first material 33. In an actual process, a fluidic first material may be used for filling the groove 32, so that the pits 321 can be fully filled.

In an embodiment, the first material 33 also covers the surface of the first insulating layer 311.

In an embodiment, the first material 33 includes a positive photoresist. In other words, the exposed portion of the first material 33 after exposure can be removed by development.

Next, S204 is performed, as illustrated in FIGS. 3E and 3F, to expose and develop the first material in the groove 32 to obtain a through via structure 34 having a smooth side wall.

In an embodiment, exposing and developing the first material 33 in the groove 32 includes the following operations.

The first material 33 in the region, outside the pits 321, in the groove 32 (the shaded portion shown in FIG. 3E) is exposed by controlling the exposure direction.

The exposed first material 33 is developed and removed, as illustrated in FIG. 3F.

In a specific embodiment, the exposure direction is perpendicular to the surface of the substrate 31. Since the pits 321 are recessed into the substrate 31, the first material 33 in the pits 321 would not be irradiated by light during exposure, so that the first material 33 in the pits 321 is retained when the through via structure 34 is formed by development. As a result, the through via structure 34 formed after development has a smooth side wall, which facilitates uniform deposition of a subsequent thin film and improves reliability of the semiconductor structure.

Referring to FIG. 3F, the pits 321 are completely filled with the first material 33. The first material 33 from the exposed surfaces of the plurality of pits 321 forms the smooth side wall of the through via structure 34.

In an embodiment, the method for forming a semiconductor structure further includes: forming a second insulating layer 35 in the through via structure 34. The second insulating layer 35 covers the bottom and side wall of the through via structure 34, as illustrated in FIG. 3G.

In a specific embodiment, the second insulating layer 35 includes but is not limited to at least one of silicon oxide or silicon nitride. Any insulating material may be used as the second insulating layer in the embodiments of the present disclosure.

In an embodiment, the elastic modulus of the first material 33 is less than the elastic modulus of the substrate 31 and the elastic modulus of the second insulating layer 35. In other words, the first material 33 has greater elasticity and lower hardness than the substrate 31 and the second insulating layer 35. The first material 33 acts as a buffer layer between the substrate 31 and the second insulating layer 35, and relieves stress applied on the second insulating layer 35 and the substrate 31 by thermal expansion of the conductive material to be formed subsequently in the through via structure. In a specific embodiment, the first material 33 may be but is not limited to polyimide. Any positive photoresist material having an elastic modulus meeting the requirements of the above embodiments may be used as the first material 33.

In an embodiment, the method for forming a semiconductor structure further includes: forming a barrier layer 36 in the through via structure 34. The barrier layer 36 at least covers the second insulating layer 35, as illustrated in FIG. 3H.

In an embodiment, the barrier layer 36 also covers the surface of the first insulating layer 311.

In an embodiment, the barrier layer 36 includes but is not limited to at least one of tantalum or titanium. Any metal material having a blocking effect may be used as the barrier layer 36 in the embodiments of the present disclosure.

In an embodiment, the method of forming a semiconductor structure further includes: forming a conductive material 37 in the through via structure 34. The barrier layer 36 separates the conductive material 37 from the second insulating layer 35, as illustrated in FIG. 3H.

In an embodiment, the method further includes: prior to forming the conductive material 37, forming a seed layer (not illustrated) on the barrier layer 36. In a specific embodiment, the seed layer material includes copper.

In an embodiment, the forming a conductive material 37 in the through via structure 34 includes: forming the conductive material 37 on the seed layer by electroplating. The conductive material 37 fills the through via structure 34 and covers the first insulating layer 311, as illustrated in FIG. 3H.

The conductive material 37, the seed layer and the barrier layer 36 on the first insulating layer 311 are removed, as illustrated in FIG. 3I.

In an embodiment, the conductive material 37 includes but is not limited to at least one of copper or tungsten. Other conductive materials may be used as the conductive material 37 in the embodiments of the present disclosure.

A further embodiment of the present disclosure provides a semiconductor structure including a substrate and a through via structure in the substrate, in which a plurality of pits that are recessed into the substrate are provided between the side wall of the through via structure and the substrate and the plurality of pits are sequentially connected along a direction in which the through via structure extends; and a first material completely filled in the plurality of pits.

The pits between the through via structure and the substrate of the semiconductor structure provided in the embodiment of the present disclosure are completely filled with the first material, so that the through via structure has a smooth side wall, which facilitates subsequent thin film deposition and improves the reliability of the semiconductor structure.

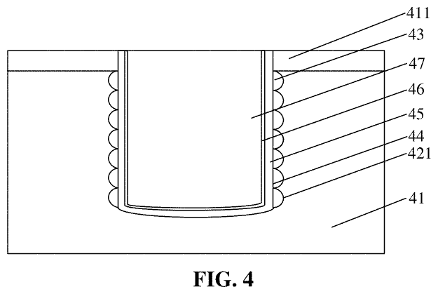

In order to make the above objectives, features and advantages of the present disclosure more clear and understandable, the package structure provided in the embodiment of the present disclosure will be further described in detail with reference to FIG. 4.

As illustrated in FIG. 4, the semiconductor structure includes a substrate 41 and a through via structure 44 in the substrate 41, in which a plurality of pits 421 recessed into the substrate 41 are provided between a side wall of the through via structure 44 and the substrate 41, and the plurality of pits 421 are sequentially connected along a direction in which the through via structure 44 extends; and a first material 43 completely filled in the pits 421.

The first material 43 from exposed surfaces of the plurality of the pits 421 forms the side wall of the through via structure 44, and the through via structure 44 has a smooth side wall.

The substrate 41 may be a semiconductor substrate, for example, an elementary semiconductor material (e.g., a silicon (Si) substrate, a germanium (Ge) substrate, etc.), a III-V compound semiconductor material (e.g., a gallium nitride (GaN) substrate, a gallium arsenide (GaAs) substrate, an indium phosphide (InP) substrate, etc.), a II-VI compound semiconductor material, an organic semiconductor material, or other semiconductor materials known in the art. In a specific embodiment, the substrate 41 is a silicon substrate and the through via structure 44 is a through silicon via structure.

In an embodiment, a first insulating layer 411 is provided on the surface of the substrate 41. The first insulating layer 411 includes an opening which exposes the through via structure 44. In a specific embodiment, the first insulating layer 411 includes but is not limited to silicon oxide. Other insulating materials may be used as the first insulating layer 411.

In an embodiment, the first material 43 includes a positive photoresist. In other words, after exposure, the exposed portion of the first material 43 will be removed by development.

In an embodiment, the semiconductor structure further includes: a second insulating layer 45 that covers the bottom and side wall of the through via structure 44. In a specific embodiment, the second insulating layer includes but is not limited to at least one of silicon oxide or silicon nitride. Any insulating material may be used as the second insulating layer in the embodiment of the present disclosure.

In an embodiment, the elastic modulus of the first material 43 is less than the elastic modulus of the substrate 41 and the elastic modulus of the second insulating layer 45. In other words, the first material 43 has greater elasticity and lower hardness than the substrate 41 and the second insulating layer 45. The first material 43 acts as a buffer layer between the substrate 41 and the second insulating layer 45, and relieves stress applied on the second insulating layer 45 and the substrate 41 by thermal expansion of the conductive material to be formed subsequently in the through via structure. In a specific embodiment, the first material 43 may be but is not limited to polyimide. Any positive photoresist material having an elastic modulus meeting the requirements of the above embodiments may be used as the first material 43.

In an embodiment, the semiconductor structure further includes a barrier layer 46 in the through via structure. The barrier layer covers the second insulating layer. In a specific embodiment, the barrier layer 46 includes but is not limited to at least one of tantalum or titanium. Any metal material having a blocking effect may be used as the barrier layer 46 in the embodiment of the present disclosure.

Referring to FIG. 4 again, in an embodiment, the semiconductor structure further includes: a conductive material 47 filled in the through via structure 44. The barrier layer 46 separates the conductive material 47 from the second insulating layer 45. In a specific embodiment, the conductive material 47 includes but is not limited to at least one of copper or tungsten. Other conductive materials may be used as the conductive material 47 in the embodiments of the present disclosure.

In an embodiment, the semiconductor structure further includes a seed layer (not illustrated) between the conductive material 47 and the barrier layer 46. In a specific embodiment, the seed layer includes copper.

The above are merely preferred embodiments of the present disclosure and are not intended to limit the protection scope of the present disclosure. Any modifications, equivalent replacements and improvements etc. made within the spirit and principles of the present disclosure shall be included in the protection scope of the present disclosure.

1. A method for forming a semiconductor structure, comprising:
providing a substrate;
forming a groove in the substrate, wherein a side wall of the groove is formed by sequential connection of a plurality of pits recessed into the substrate;
forming a first material in the groove, wherein the pits are completely filled with the first material;
exposing and developing the first material in the groove to obtain a through via structure.

2. The method for forming a semiconductor structure according to claim 1, wherein the first material comprises a positive photoresist.

3. The method for forming a semiconductor structure according to claim 1, wherein the exposing and developing the first material in the groove comprises:
exposing the first material in a region, outside of the pits, in the groove by controlling an exposure direction; and
removing the exposed first material by developing.

4. The method for forming a semiconductor structure according to claim 1, wherein a first insulating layer is provided on a surface of the substrate; the method comprising: prior to forming the groove, forming an opening in the first insulating layer which exposes the surface of the substrate, wherein a position of the opening corresponds to a position of the groove.

5. The method for forming a semiconductor structure according to claim 1, further comprising: forming a second insulating layer in the through via structure, wherein the second insulating layer covers a bottom and a side wall of the through via structure.

6. The method for forming a semiconductor structure according to claim 5, wherein the second insulating layer comprises at least one of silicon oxide or silicon nitride.

7. The method for forming a semiconductor structure according to claim 5, wherein an elastic modulus of the first material is smaller than an elastic modulus of a material of the substrate and an elastic modulus of the second insulating layer.

8. The method for forming a semiconductor structure according to claim 5, further comprising: forming a barrier layer in the through via structure, wherein the barrier layer covers at least the second insulating layer.

9. The method for forming a semiconductor structure according to claim 8, wherein the barrier layer comprises at least one of tantalum or titanium.

10. The method for forming a semiconductor structure according to claim 8, further comprising: forming a conductive material in the through via structure, wherein the barrier layer separates the conductive material from the second insulating layer.

11. The method for forming a semiconductor structure according to claim 10, wherein the conductive material comprises at least one of copper or tungsten.

12. A semiconductor structure, comprising:
a substrate and a through via structure in the substrate, wherein a plurality of pits that are recessed into the substrate are provided between a side wall of the through via structure and the substrate, and the plurality of pits are sequentially connected along a direction in which the through via structure extends; and
a first material completely filled in the plurality of pits.

13. The semiconductor structure according to claim 12, wherein the first material comprises a positive photoresist.

14. The semiconductor structure according to claim 12, further comprising: a second insulating layer that covers a side wall of the through via structure.

15. The semiconductor structure according to claim 14, wherein the second insulating layer comprises at least one of silicon oxide or silicon nitride.

16. The semiconductor structure according to claim 14, wherein an elastic modulus of the first material is less than an elastic modulus of a material of the substrate and an elastic modulus of the second insulating layer.

17. The semiconductor structure according to claim 14, further comprising: a barrier layer located in the through via structure and covering the second insulating layer.

18. The semiconductor structure according to claim 17, wherein the barrier layer comprises at least one of tantalum or titanium.

19. The semiconductor structure according to claim 17, further comprising: a conductive material filled in the through via structure, wherein the barrier layer separates the conductive material from the second insulating layer.

20. The semiconductor structure according to claim 19, wherein the conductive material comprises at least one of copper or tungsten.
